(19) United States
(12) Patent Application Publication
(10) Pub. No.: US 2021/0328114 A1
(43) Pub. Date: Oct. 21, 2021

(54) OPTOELECTRONIC SEMICONDUCTOR COMPONENT AND METHOD OF MANUFACTURING AN OPTOELECTRONIC SEMICONDUCTOR COMPONENT

(71) Applicant: Osram OLED GmbH, Regensburg (DE)

(72) Inventors: Ivar TANGRING, Regensburg (DE); Rebecca ROEMER, Regensburg (DE)

(21) Appl. No.: 17/270,066

(22) PCT Filed: Aug. 7, 2019
(86) PCT No.: PCT/EP2019/071249

§ 371 Date: Feb. 22, 2021

(30) Foreign Application Priority Data
Aug. 23, 2018 (DE) 10 2018 120 584.8

(51) Int. Cl. H01L 33/50; C09K 11/02

(52) U.S. Cl. CPC H01L 33/504; H01L 2933/0041; C09K 11/02

(57) ABSTRACT

An optoelectronic semiconductor component may include a semiconductor chip that emits radiation of a first wavelength range from a radiation exit area and a conversion layer that has a plurality of single conversion layers. Each conversion layer may have a phosphor that converts the radiation from a first wavelength range to a second wavelength range. Each conversion layer may also have a concentration of the phosphor in the individual conversion layers different from one another.

### CROSS-REFERENCE TO RELATED APPLICATIONS

The present application is a national stage entry according to 35 U.S.C. § 371 of PCT application No.: PCT/EP2019/071249 filed on Aug. 7, 2019; which claims priority to German Patent Application Serial No.: 10 2018 120 584.8 filed on Aug. 23, 2018; all of which are incorporated herein by reference in their entirety and for all purposes.

### TECHNICAL FIELD

An optoelectronic semiconductor device is specified. In addition, a method of manufacturing an optoelectronic semiconductor device is specified.

### BACKGROUND

A object to be solved is to specify a conversion element with increased efficiency and/or improved thermal management. In addition, a method of manufacturing an optoelectronic semiconductor device is to be specified.

### SUMMARY

Advantageous embodiments of the optoelectronic semiconductor device and the method are subject of the respective dependent claims.

According to one embodiment, the optoelectronic semiconductor device comprises a semiconductor chip that, in operation, emits electromagnetic radiation of a first wavelength range from a radiation exit surface. In a non-limiting embodiment, the optoelectronic semiconductor chip, such for example a light-emitting diode chip, comprises an epitaxially grown semiconductor layer sequence having an active region adapted to generate electromagnetic radiation. For this purpose, the active region has, for example, a pn junction, a double heterostructure, a single quantum well structure or a multiple quantum well structure. In a non-limiting embodiment, the semiconductor chip emits electromagnetic radiation from a blue wavelength range.

According to a further embodiment, the optoelectronic semiconductor device comprises a conversion layer. The conversion layer is arranged on the radiation exit surface of the semiconductor chip. The conversion layer converts electromagnetic radiation of the first wavelength range into electromagnetic radiation of a second wavelength range which is different from the first wavelength range.

According to an embodiment, the conversion layer comprises at least two single conversion layers. It is also possible that the conversion layer has more than two single conversion layers. Furthermore, the conversion element may comprise two or more than two single conversion layers. In a non-limiting embodiment, the single conversion layers of the conversion layer are arranged one above the other in a stacking direction. For example, two single conversion layers are in direct contact with each other.

According to a further embodiment, each single conversion layer comprises a phosphor that converts electromagnetic radiation of the first wavelength range into electromagnetic radiation of the second wavelength range. In other words, the phosphor imparts wavelength-converting properties to the single conversion layers and the conversion layer.

The term “wavelength-converting” is used here to mean that irradiated electromagnetic radiation of a certain wavelength range is converted into electromagnetic radiation of another, such as longer wavelength range. As a rule, a wavelength-converting element absorbs electromagnetic radiation of an irradiated wavelength range, converts it by electronic processes on atomic and/or molecular level into electromagnetic radiation of another wavelength range and emits the converted electromagnetic radiation again. In particular, pure scattering or pure absorption is not understood as wavelength-converting.

According to a further embodiment, the phosphor comprises an activator. In a non-limiting embodiment, the activator is incorporated into a crystalline, for example ceramic, host lattice. The activator imparts the wavelength-converting properties to the phosphor. The electronic structure of the activator is modified by incorporation into the host lattice such that electromagnetic radiation of the excitation wavelength is absorbed in the material and excites an electronic transition in the activator-based phosphor, which returns to the ground state while emitting electromagnetic radiation of the second wavelength range. In a non-limiting embodiment, an activator concentration of the phosphor in the single conversion layers is different from each other.

According to an embodiment of the optoelectronic semiconductor device, the phosphor comprises a host lattice into which an activator is introduced. Here, the host lattice and the activator of the phosphor in the single conversion layers are the same in a non-limiting embodiment. In other words, the single conversion layers each have a phosphor that differs only in terms of the activator concentration.

Furthermore, it is also possible that the host lattice of the phosphors of the single conversion layers differs with respect to its elemental composition, but not with respect to its underlying crystal structure. For example, the single conversion layers each comprise a garnet phosphor with a wurtzite crystal structure, whereby however the lattice sites are occupied by different elements. Thus, for example, one of the single conversion layers may comprise a YAG phosphor having the chemical formula Y₃Al₅O₁₂:Ce³⁺, while another single conversion layer comprises a LuAG phosphor having the chemical formula Lu₃A₁₅O₁₂:Ce³⁺, in which the yttrium is completely replaced by lutetium. If the single conversion layers each have a nitride phosphor, such as a SCASN phosphor with the chemical formula (Ca,Sr)AlSiN₃:Eu²⁺ and an orthorhombic crystal structure, the ratio of Ca to Sr in the single conversion layers may differ, for example.

According to an embodiment, the optoelectronic semiconductor device comprises a semiconductor chip which emits in operation electromagnetic radiation of the first wavelength range from a radiation exit surface and a conversion layer comprising at least two single conversion layers. In this embodiment, each single conversion layer comprises a phosphor that at least partially converts electromagnetic radiation of the first wavelength range into electromagnetic radiation of the second wavelength range, wherein an activator concentration of the phosphor in the single conversion layers is different from each other.

According to one embodiment, the conversion layer is applied to the radiation exit surface. In a non-limiting embodiment, the single conversion layer located closer to the radiation exit surface comprises a phosphor whose activator concentration is smaller than the activator concentration of the phosphor in the single conversion layer which is further away from the radiation exit surface.

According to one embodiment, the conversion layer comprises a plurality of single conversion layers. In a non-limiting embodiment, the activator concentration of the phosphor in the single conversion layers increases starting from the radiation exit surface of the semiconductor chip. For example, the activator concentration of the phosphor in the single conversion layers increases continuously starting from the radiation exit surface of the semiconductor chip.

According to a further embodiment of the optoelectronic semiconductor device, the phosphor is formed as a plurality of phosphor particles. The phosphor particles are embedded in a matrix. The phosphor particles have a diameter between 1 micrometer inclusive and 70 micrometers inclusive, such as between 5 inclusive and 50 micrometers inclusive.

For example, the phosphor of a single conversion layer has an absorption cross-section that is different from the absorption cross-section of the phosphor of another single conversion layer. The absorption cross section depends on the penetration depth of the electromagnetic radiation of the first wavelength range into the phosphor particle, the activator concentration of the phosphor particle and the surface of the phosphor particle. In a non-limiting embodiment, the absorption cross-section is a measure of how much electromagnetic radiation of the first wavelength range is absorbed by the phosphor and converted into electromagnetic radiation of the second wavelength range.

In a non-limiting embodiment, the matrix comprises or is formed from a silicone, an epoxy, or a mixture of these materials.

According to one embodiment, the concentration of the phosphor particles in the matrix is between 15 vol % inclusive and 50 vol %, inclusive. In a non-limiting embodiment, the concentration of the phosphor particles in the matrix is between 20 vol % inclusive and 25 vol %, inclusive. For example, the concentration of the phosphor particles in the matrix is between about 23 vol %.

According to at least one embodiment, the plurality of the phosphor particles comprises a plurality of first phosphor particles and a plurality of second phosphor particles. The first phosphor particles have a higher activator concentration than the second phosphor particles, and the first phosphor particles are more lightweighted than the second phosphor particles. In a non-limiting embodiment, the single conversion layer with the first phosphor particles is further away from the radiation exit surface of the semiconductor chip than the single conversion layer with the second phosphor particles. In a non-limiting embodiment, the first phosphor particles and the second phosphor particles comprise the same host lattice or the same crystal structure of the host lattice and the same activator and differ only in the activator concentration.

According to one embodiment, the optoelectronic semiconductor device comprises phosphor particles comprising a garnet phosphor and/or a nitride phosphor or formed from a garnet phosphor and/or a nitride phosphor. In a non-limiting embodiment, the nitride phosphor has europium as an activator and the garnet phosphor has cerium.

For example, the nitride phosphor may be an alkaline earth silicon nitride, an oxynitride, an aluminum oxynitride, a silicon nitride, or a sialon. For example, the nitride phosphor is (Ca,Sr,Ba)AlSiN₃:Eu²⁺, (Ca,Sr)AlSiN₃:Eu²⁺ (SCASN), Sr(Ca,Sr)Al₂Si₂N₆:Eu²⁺ or M₂Si₅N₈:Eu²⁺ with M=Ca, Ba or Sr alone or in combination. In a non-limiting embodiment, the nitride phosphor comprises europium as activator. In a non-limiting embodiment, the nitride phosphor converts electromagnetic radiation of the first wavelength range into electromagnetic radiation of the second wavelength range. The second wavelength range is in the red wavelength range. In a non-limiting embodiment, the nitride phosphor absorbs electromagnetic radiation in the blue wavelength range and converts it to electromagnetic radiation in the red wavelength range.

In a non-limiting embodiment, the garnet phosphor is a LuAG phosphor having the chemical formula Lu₅Al₅O₁₂:Ce³⁺, LuAGaG phosphor having the chemical formula Lu₃(Al,Ga)₅O₁₂:Ce³⁺, a YAG phosphor having the chemical formula Y₅Al₅O₁₂:Ce³⁺, a YAGaG phosphor having the chemical formula Y₃(Al,Ga)₅O₁₂:Ce³⁺ or another garnet phosphor having the general chemical formula (Lu,Y)₃(Al,Ga)₅O₁₂:Ce³⁺. In a non-limiting embodiment, the garnet phosphor converts electromagnetic radiation of the first wavelength range into electromagnetic radiation of the second wavelength range. The second wavelength range is in the green and/or yellow wavelength range. In a non-limiting embodiment, the garnet phosphor absorbs electromagnetic radiation in the blue wavelength range and converts it to electromagnetic radiation in the green and/or yellow wavelength range.

If the phosphor is a garnet phosphor, the activator concentration of the garnet phosphor in the single conversion layer which is located closest to the radiation exit surface is between 0.5 mol % inclusive and 2 mol % inclusive.

According to another embodiment, the activator concentration of the garnet phosphor in the single conversion layer which is furthest from the radiation exit surface is between 1.5 mol % inclusive and 5 mol % inclusive.

If the phosphor is a nitride phosphor, the activator concentration of the nitride phosphor in the single conversion layer which is located closest to the radiation exit surface is between 0.5 mol % inclusive and 8 mol % inclusive.

According to another embodiment, the activator concentration of the nitride phosphor in the single conversion layer which is furthest from the radiation exit surface is between 6 mol % inclusive and 20 mol % inclusive.

According to another embodiment, the activator concentration of the phosphor in the single conversion layer which is located furthest from the radiation exit surface differs from the activator concentration of the phosphor in the single conversion layer which is located closest to the radiation exit surface by at least 0.5 mol %. If the activator concentration of the garnet phosphor in the single conversion layer located closest to the radiation exit surface is 0.5 mol %, the activator concentration in the single conversion layer located furthest from the radiation exit surface is greater, such as greater than 1. For example, the activator concentration is about 1 mol %.

According to one embodiment, the conversion layer comprises a plurality of single conversion layers, and a thickness of the single conversion layers decreases starting from the radiation exit surface of the semiconductor chip. For example, the conversion layer comprises two single conversion layers, wherein the single conversion layer located furthest from the radiation exit surface has a smaller thickness than the single conversion layer located closest to the radiation exit surface. Thinner single conversion layers lead to a reduction of a maximum temperature in the single conversion layers due to shorter paths of heat to a heat sink, which leads to an extended lifetime of the optoelectronic semiconductor device. The heat of the single conversion layers is usually dissipated via the semiconductor chip, which serves as a heat sink. In this way, the maximum temperature in the semiconductor device is reduced with advantage. A low maximum temperature advantageously leads to a lower degradation of the matrix.

According to another embodiment, the optoelectronic semiconductor device comprises single conversion layers comprising a red emitting phosphor and/or a green emitting phosphor and/or a yellow emitting phosphor. For example, the single conversion layers have a garnet phosphor and a nitride phosphor. In a non-limiting embodiment, the phosphors convert only a portion of the electromagnetic radiation of the semiconductor chip, while a portion of the electromagnetic radiation of the semiconductor chip remains unconverted. In a non-limiting embodiment, the semiconductor device emits white light in this case.

In a non-limiting embodiment, the red-emitting phosphor is a nitride phosphor, such as (Sr,Ca,Ba)AlSiN₃ with europium as activator. In particular, the garnet phosphors emit electromagnetic radiation from the green and yellow wavelength ranges. In a non-limiting embodiment, the conversion layer comprises between 15 vol % inclusive and 50 vol % inclusive of phosphor particles, such as between 20 vol % inclusive and 25 vol % inclusive of phosphor particles, wherein, for example, between 70 vol % inclusive and 95 vol % inclusive of the phosphor particles being garnet phosphors. For example, the proportion of garnet phosphors in the phosphor particles is about 85 vol %.

For example, electromagnetic radiation from the blue wavelength range of the semiconductor chip is partially converted in the phosphors to electromagnetic radiation from the green, yellow and/or red wavelength range. For example, the green wavelength range is between 490 nanometers inclusive and 550 nanometers inclusive. The yellow wavelength range is, for example, between 550 nanometers inclusive and 590 nanometers inclusive. The red wavelength range is, for example, between 590 nanometers inclusive and 780 nanometers, inclusive. By means of the red emitting phosphor and/or the green emitting phosphor and/or the yellow emitting phosphor, it is advantageously possible to generate mixed light having a color locus in the white range from blue radiation from a semiconductor device.

According to one embodiment, the conversion layer of the optoelectronic semiconductor device converts electromagnetic radiation of the first wavelength range as completely as possible into electromagnetic radiation of the second wavelength range. Here, the semiconductor chip emits electromagnetic radiation from the blue and/or ultraviolet spectral range. This achieves a particularly high efficiency of the semiconductor device.

According to a further embodiment, the optoelectronic semiconductor device comprises an optical element. In a non-limiting embodiment, the optical element is disposed on or over a surface of the conversion layer that is parallel to the radiation exit surface of the semiconductor chip. In a non-limiting embodiment, the optical element comprises or is formed of a plastic or a glass. In a non-limiting embodiment, the optical element has a silicone or is formed from a silicone.

The optoelectronic semiconductor device can be manufactured using the method described below. Features and embodiments implemented only in connection with the semiconductor device can also be used in the method, and vice versa.

According to one embodiment of the method of fabricating a optoelectronic semiconductor device, a semiconductor chip that emits in operation electromagnetic radiation of the first wavelength range from a radiation exit surface is first provided.

According to one embodiment of the method, a conversion layer is applied, such as subsequently in the radiation direction above the radiation exit surface. The conversion layer is arranged in direct contact on the radiation exit surface of the semiconductor chip.

According to an embodiment, the conversion layer comprises at least two single conversion layers. In a non-limiting embodiment, the single conversion layers are arranged one above the other in a stacking direction. For example, two single conversion layers are in direct contact with each other in each case.

According to another embodiment, each single conversion layer comprises a phosphor that converts electromagnetic radiation of the first wavelength range into electromagnetic radiation of the second wavelength range.

According to one embodiment of the method, the phosphor comprises an activator. In a non-limiting embodiment, the activator concentration of the phosphor in the single conversion layers is different from each other. In a non-limiting embodiment, the single conversion layer which is located closest to the radiation exit surface has a lower activator concentration than the single conversion layer which is located furthest from the radiation exit surface.

According to a further embodiment of the method, the single conversion layers of the conversion layer are applied one after the other by means of spray coatings. In a non-limiting embodiment, an single conversion layer with a phosphor of a lower activator concentration is first applied to the radiation exit surface of the semiconductor chip. The phosphor is introduced as phosphor particles in a matrix which is initially in liquid form. In a non-limiting embodiment, a thinner single conversion layer with a phosphor of a higher activator concentration is then applied to the single conversion layer with a lower activator concentration. Here, too, the phosphor is present as phosphor particles introduced into a liquid matrix.

According to a further embodiment of the method, the phosphors are also present as phosphor particles embedded in a matrix. The matrix is initially in liquid form. The phosphor particles are sedimented in the matrix.

In a sedimentation method, the surface to be coated is usually provided in a volume that is filled with the matrix comprising the phosphor particles. The phosphor particles then settle on the surface to be coated due to gravity. The settling of the phosphor particles can also be accelerated here by centrifugation. The use of a diluted matrix also usually accelerates the sedimentation method. After the phosphor particles have settled, the matrix is cured.

A characteristic of a conversion layer and/or a single conversion layer applied by means of a sedimentation method is that all surfaces on which the phosphor particles can settle due to gravity are coated with the conversion layer and/or the single conversion layer. Furthermore, the phosphor particles of a sedimented conversion layer and/or a sedimented single conversion layer are usually in direct contact with each other.

According to one embodiment of the method, phosphor particles are provided comprising a plurality of first phosphor particles and a plurality of second phosphor particles, wherein the first phosphor particles have a higher activator concentration than the second phosphor particles and the first phosphor particles are more lightweighted than the second phosphor particles. In a non-limiting embodiment, the first phosphor particles and the second phosphor particles here have the same host lattice or the same crystal structure of the host lattice and the same activator and differ only in the activator concentration.

According to a further embodiment of the method, the phosphor particles are introduced into the matrix and sedimented, so that during sedimentation a single conversion layer with first phosphor particles and a single conversion layer with second phosphor particles are formed, wherein the single conversion layer with the first phosphor particles is further away from the radiation exit surface of the semiconductor chip than the single conversion layer with the second phosphor particles. That is, the single conversion layer located directly at the radiation exit surface has larger phosphor particles with a lower activator concentration, whereas the single conversion layer located further from the radiation exit surface has smaller phosphor particles with a higher activator concentration.

One idea of the present semiconductor device is to provide in the conversion layer at least two single conversion layers whose phosphor particles differ only in terms of their activator concentration, while the host lattice or the crystal structure of the host lattice and the activator are the same. In a non-limiting embodiment, the activator concentration is higher in the single conversion layer that is further away from the radiation exit surface. Since the intensity of the radiation from the semiconductor chip generally decreases continuously with distance from the radiation exit surface, usually exponentially, the amount of converted radiation is adjusted in this way so that the total conversion does not exceed a critical limit at which efficiency decreases. The activator concentration within the conversion layer can thus be optimized in terms of conversion efficiency and thermal management. In particular, the maximum temperature within the semiconductor device can be advantageously reduced in this way.

The reduced maximum temperature within the semiconductor device advantageously allows the use of materials for the matrix that have a lower thermal stability, such as silicones with an increased refractive index. This usually increases the amount of electromagnetic radiation of the first wavelength range that is coupled out of the semiconductor chip and decreases the scattering by the phosphor particles. These effects usually lead with advantage to an increased brightness of the semiconductor device.

In addition, the reduced maximum temperature within the semiconductor device advantageously leads to lower quenching effects within the phosphor. This also increases the brightness of the semiconductor device.

In addition, it is possible to achieve thinner conversion layers, so that the overall thickness of the semiconductor device is reduced with advantage.

Finally, the black and white contrast at an edge of the conversion layer with advantage is usually increased because the lateral distribution of the electromagnetic radiation within the conversion layer is usually reduced.

### BRIEF DESCRIPTION OF THE DRAWINGS

The accompanying drawings serve to provide an understanding of non-limiting embodiments. The drawings illustrate non-limiting embodiments and, together with the description, serve to explain them. Further non-limiting embodiments and many of the intended advantages will become apparent directly from the following detailed description. The elements and structures shown in the drawings are not necessarily shown to scale relative to each other.

FIGS. 1 and 2, respectively, a schematic sectional view of an optoelectronic semiconductor device according to an embodiment example,

FIG. 3 shows a schematic diagram of the relative radiation intensity of blue light emitted by the semiconductor chip as a function of the distance d from the radiation exit surface according to the embodiment example of FIGS. 1 and 2,

FIGS. 4 to 6 each a schematic sectional view of an optoelectronic semiconductor device according to a respective embodiment example,

FIGS. 7 to 10 schematic sectional views of various method stages of a method of manufacturing an optoelectronic semiconductor device according to an embodiment example.

### DETAILED DESCRIPTION

Elements that are identical, similar or have the same effect are given the same reference signs in the figures. The figures and the proportions of the elements shown in the figures are not to be regarded as true to scale. Rather, individual elements, in particular layer thicknesses, may be shown exaggeratedly large for better representability and/or understanding.

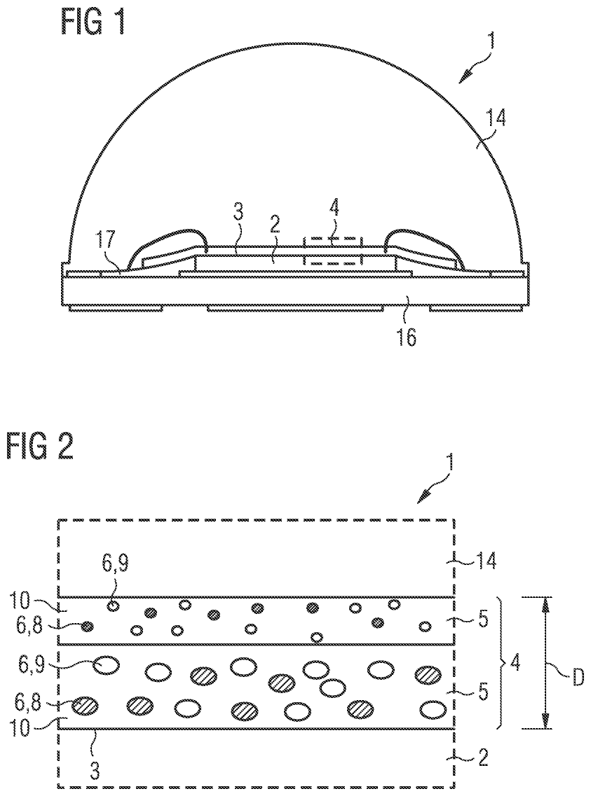

The optoelectronic semiconductor device 1 according to the embodiment example of FIGS. 1 and 2 comprises a semiconductor chip 2 and a conversion layer 4. In operation, the semiconductor chip 2 emits electromagnetic radiation of a first wavelength range, in this case blue light, from a radiation exit surface 3.

The conversion layer 4 is provided on the radiation exit surface 3. In addition, the optoelectronic semiconductor device 1 has an optical element 14 that adjusts the radiation characteristic of the semiconductor device in a desired manner.

The semiconductor chip 2 is mounted on a thermal connection point 16 of a connection carrier. At the side, the semiconductor chip 2 is surrounded by a diffuse reflective encapsulant 17. For example, the diffuse reflective encapsulant 17 has a silicone with titanium dioxide particles.

The conversion layer 4 comprises at least two single conversion layers 5. The single conversion layers 5 can be seen in the enlarged view of FIG. 2, which shows the section marked with a rectangle in FIG. 1. Each single conversion layer 5 has a phosphor that converts electromagnetic radiation of a first wavelength range into electromagnetic radiation of a second wavelength range. The activator concentration of the phosphors in the single conversion layers 5 is different from each other, while the host lattice or the crystal structure of the host lattice and the activator are the same.

Phosphor particles 6 are embedded in a matrix 10 in the single conversion layers 5. The phosphor particles 6 have or are formed from a garnet phosphor 8 and/or a nitride phosphor 9. The garnet phosphor 8 may be, for example, a mixture of a LuAGaG phosphor and a YAG phosphor, while the nitride phosphor 9 may be, for example, a SCASN phosphor. The garnet phosphor 8 converts blue light from the semiconductor chip 2 into yellow-green radiation, while the nitride phosphor 9 converts blue light from the semiconductor chip 2 into red radiation. Together with unconverted blue radiation from the semiconductor chip, the semiconductor device emits mixed-color white radiation, such as in the white range. For example, the correlated color temperature of the mixed color radiation has a value of about 5000 K, while the color rendering index of the mixed color radiation is, for example, at least 70.

An activator concentration of the phosphor particles 6 of the garnet phosphor 8 increases starting from the radiation exit surface 3 of the semiconductor chip 2. For example, the single conversion layer 5 located closer to the radiation exit surface 3 has a garnet phosphor 8 whose activator concentration is smaller than the activator concentration of the garnet phosphor 8 in the single conversion layer 5 located further from the radiation exit surface 3. In the present case, the matrix comprises a silicone.

The thickness dₙ of the single conversion layer 5, which is further away from the radiation exit surface 3, can be determined, for example, using the following formula, based on a conventional conversion layer that has only a single single conversion layer of thickness 2*d₀:

$${d}_{n} = [ \frac{vol {\%}_{pg}}{( \frac{{c}_{n}}{{c}_{o}} )} + ( vol {\%}_{pa} - vol {\%}_{pg} ) ] \times {d}_{o} ,$$

where vol %_{pg} is the volume fraction of the garnet phosphors 8 and vol %ₚₐ is 1. Where c₀ is also the activator concentration of the garnet phosphors 8 in the single conversion layer 5 located closer to the radiation exit surface 3, and cₙ is the activator concentration of the garnet phosphors 8 in the single conversion layer 5 located further from the radiation exit surface 3.

For the values d₀=30 micrometer, vol %_{pg}=0.85, cₙ=2 and c₀=1, this results in:

$${d}_{n} = [ \frac{0.85}{( \frac{2}{1} )} + 0.15 ] \times 30 μ m = 17.25 μ m .$$

The thickness D of the conversion layer 4 is thus approximately 30 micrometers+17.25 micrometers=47.3 micrometers. Compared to a conventional conversion layer, which has a thickness of 60 micrometers, the thickness D of the conversion layer 4 is reduced by approximately 21%.

In the case of the garnet phosphors 8, the absorption cross-section in the single conversion layer 5, which is further away from the radiation exit surface 3, is approximately doubled in the above calculation example. This means that the number of phosphor particles 6 can be reduced in the single conversion layer 5, which is further away from the radiation exit surface 3. This also results in a reduced thickness of this single conversion layer 5. Thinner single conversion layers 5 advantageously lead to a reduction of the maximum temperature in the single conversion layers 5 due to shorter paths of heat to the semiconductor chip 2, which serves as a heat sink, which leads to an extended service life of the optoelectronic semiconductor device 1.

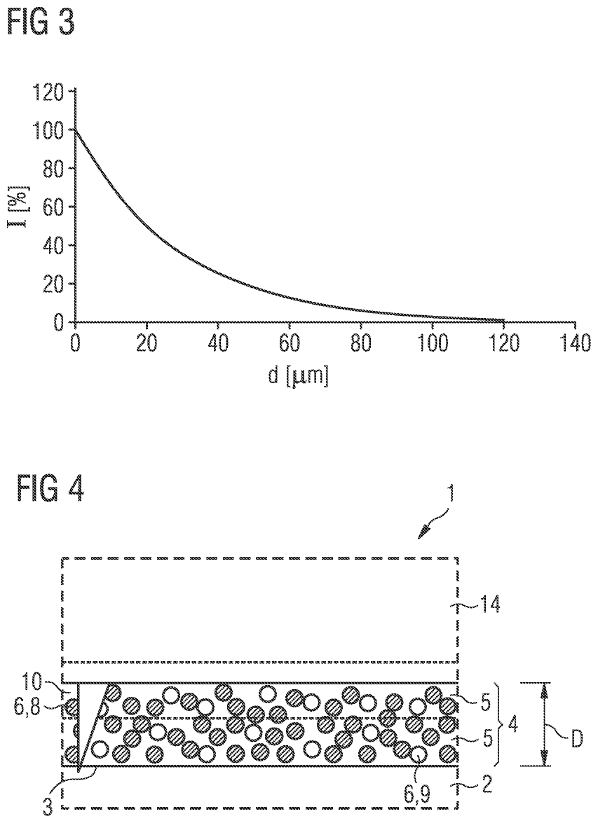

FIG. 3 shows a schematic diagram of the relative radiation intensity I of the blue light of the semiconductor chip 2 in % within the conversion layer 4 as a function of the distance d in micrometers from the radiation exit surface 3 of the semiconductor chip 2. The intensity of the blue light decreases exponentially here. The relative intensity of 100% refers to the radiation intensity emitted by the semiconductor chip 2 at the radiation exit surface 3.

The phosphor particles 6 in the single conversion layer 5, which are further away from the radiation exit surface 3, sense lower radiation intensity than the phosphors located closer to the radiation exit surface 3 due to the exponential decrease in the radiation intensity.

Thus, the absorption cross-section of the garnet phosphors 8 is doubled and the phosphor particles 6 are inserted at a position relative to the radiation exit surface 3 of the semiconductor chip 2 where the radiation density of the blue light is half.

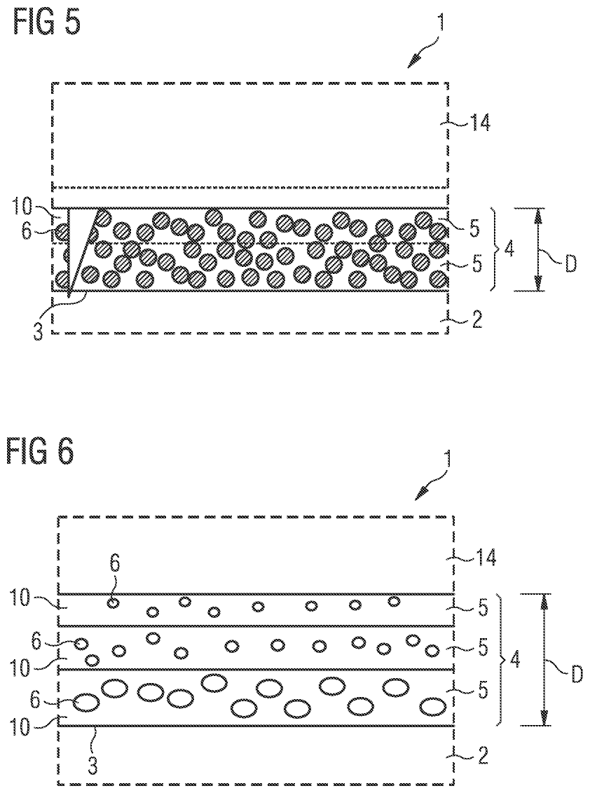

The optoelectronic semiconductor device 1 according to the embodiment example of FIG. 4 has a conversion layer 4 arranged on the semiconductor chip 2. The conversion layer 4 has two single conversion layers 5, with phosphor particles 6 embedded in a matrix 10. The single conversion layers 5 have a red-emitting phosphor and/or a green-emitting phosphor and/or a yellow-emitting phosphor. The phosphors are embedded in a matrix 10. The red-emitting phosphor is a nitride phosphor 9, whereas the green- and yellow-emitting phosphors are garnet phosphors 8. The semiconductor device emits white light.

An optical element 14, for example a lens, is disposed above the conversion layer 4. For example, by increasing the activator concentration of the garnet phosphors 8 in the single conversion layer 5 which is further away from the radiation exit surface 3, the thickness of the single conversion layer 5 can be substantially reduced.

The optoelectronic semiconductor device according to the embodiment example of FIG. 5 differs from the embodiment example of FIG. 2 in the phosphor particles 6. Here, only garnet phosphors 8 are embedded in the conversion layer 4. These are garnet phosphors which convert blue radiation into green-yellow radiation. The single conversion layers 5 therefore have only two different phosphors. Here, the electromagnetic radiation of the first wavelength range, so the blue light of the semiconductor chip 2, is converted as completely as possible by the phosphor into electromagnetic radiation of the second wavelength range, so in green-yellow light. For complete conversion of the electromagnetic radiation of the first wavelength range of a full conversion, a comparatively large thickness D of the conversion layer 4 is required in order to absorb the electromagnetic radiation of the first wavelength range emitted by the semiconductor chip 2 as completely as possible. The conversion layer 4 is divided into two or more single conversion layers 5 arranged one above the other. Due to a higher activator concentration of the phosphor particles 6 in the single conversion layer 5, which is further away from the radiation exit surface 3, its thickness can be reduced. Due to the lower radiation intensity in the single conversion layer 5, which is further away from the radiation exit surface 3, thermal and optical quenching effects (thermal and optical quenching) in individual phosphor particles 6 can be reduced. The single conversion layers 5 may be applied, for example, by means of spray coatings.

The thickness D of a conventional conversion layer is approximately 120 micrometers, for example. At least 98% of the blue light of the semiconductor chip 2 is converted by the conversion layer 4.

If the thickness D of the conventional conversion layer has 120 micrometers, the single conversion layer 5, which is located closer to the radiation exit surface 3 of the semiconductor chip 2, may have a thickness of approximately 21 micrometers and a single absorption cross section. Now, if the absorption cross-section of the garnet phosphors in the single conversion layer 5 located further from the radiation exit surface 3 of the semiconductor chip 2 doubles, the thickness of the single conversion layer 5 located further from the radiation exit surface 3 of the semiconductor chip 2 is approximately halved. For the thickness D of the conversion layer 4, it follows that 21 micrometers+about (99/2) micrometers=about 70 micrometers. The thickness D of the conversion layer 4 can thus be reduced by about 50 micrometers compared to the thickness of a conventional conversion layer by doubling the absorption cross-section of the garnet phosphors 8 in the single conversion layer 5, which is located further away from the radiation exit surface 3.

If the thickness D of the conventional conversion layer has 120 micrometers, the single conversion layer 5 located closer to the radiation exit surface 3 of the semiconductor chip 2 may have a thickness of about 33 micrometers and a single absorption cross section. Now, if the absorption cross-section of the garnet phosphors 8 in the single conversion layer 5 located further from the radiation exit surface 3 of the semiconductor chip 2 triples, the thickness of the single conversion layer 5 located further from the radiation exit surface 3 of the semiconductor chip 2 decreases by approximately ⅔. For the thickness D of the conversion layer 4, it follows from this that 33 micrometers+(87/2) micrometers=62 micrometers. The thickness D of the conversion layer 4 can thus be approximately halved by tripling the absorption cross-section of the garnet phosphors 8 in the single conversion layer 5, which is arranged further away from the radiation exit surface 3.

If the thickness D of the conventional conversion layer has 120 micrometers, the single conversion layer 5 located closer to the radiation exit surface 3 of the semiconductor chip 2 may have a thickness of about 41 micrometers and a single absorption cross section. Now, if the absorption cross-section of the garnet phosphors 8 in the single conversion layer 5 located further from the radiation exit surface 3 of the semiconductor chip 2 quadruples, the thickness of the single conversion layer 5 located further from the radiation exit surface 3 of the semiconductor chip 2 decreases by approximately ¾. For the thickness D of the conversion layer 4, it follows from this that 41 micrometers+(79/4) micrometers=61 micrometers. This value of the thickness D of conversion layer 4 is thus only slightly smaller than the value of the thickness D of a conversion layer 4 in which the absorption cross section of the garnet phosphors 8 in the single conversion layer 5, which is further away from the radiation exit surface 3 of the semiconductor chip 2, has been tripled. Therefore, this value is probably a lower limit for the thickness D of the conversion layer 4 that can be obtained with the present concept.

The optoelectronic semiconductor device according to the embodiment example of FIG. 6 differs from the embodiment example shown in FIG. 5 in the number of single conversion layers 5. Three single conversion layers 5 are used instead of two single conversion layers 5. Garnet phosphors 8 with three different activator concentrations and thus also with three different absorption cross sections are used. The aim is to achieve a full conversion of the electromagnetic radiation in the first wavelength range, at present blue light.

For example, the single conversion layer 5 located closest to the radiation exit surface 3 of the semiconductor chip 2 has an activator concentration c₀=1 and a thickness of about 21 micrometers. In the single conversion layer 5 following in the radiation exit direction of the semiconductor chip 2, the absorption cross-section of the garnet phosphor 8 is doubled, so that the thickness of this single conversion layer 5 is reduced to 10 micrometers. Finally, the conversion layer 4 has a single conversion layer 5, which is again arranged subsequently in the radiation direction of the semiconductor chip 2 and is positioned furthest from the radiation exit surface 3 of the semiconductor chip 2. In the present case, this single conversion layer 5 has a garnet phosphor 8 whose absorption cross section is quadrupled compared with the absorption cross section of the garnet phosphor 8 in the single conversion layer 5 which is arranged closest to the radiation exit surface 3 of the semiconductor chip 2. This single conversion layer 5 has a thickness of approximately 20 micrometers. The thickness D of the conversion layer 4 is thus obtained to be 51 micrometers starting from a conventional conversion layer 4 having a thickness of about 120 micrometers. The thickness D of the conversion layer 4 is thus significantly smaller than the thickness of a conventional conversion layer 4. This leads with advantage to a reduction in scattering and to a reduction in the maximum temperature in the conversion layer 4.

A further reduction of the thickness D of the conversion layer 4 can be achieved by using three similarly thick single conversion layers 5. For example, the single conversion layer 5 located closest to the radiation exit surface 3 of the semiconductor chip 2 has a thickness of 18 micrometers and garnet phosphors 8 with an activator concentration c₀=1. In contrast, the single conversion layer 5 which is arranged directly downstream in the radiation direction has a thickness of approximately 14 micrometers and garnet phosphors 8 with an absorption cross-section 1.8 times, which in turn is arranged downstream in the radiation direction. The single conversion layer 5 has a thickness of about 14.5 micrometers and garnet phosphors 8 with a fivefold absorption cross section. The thickness D of the conversion layer 4 is thus about 46.5 micrometers and is thus about 61% thinner than the thickness of a conventional conversion layer 4 of about 120 micrometers.

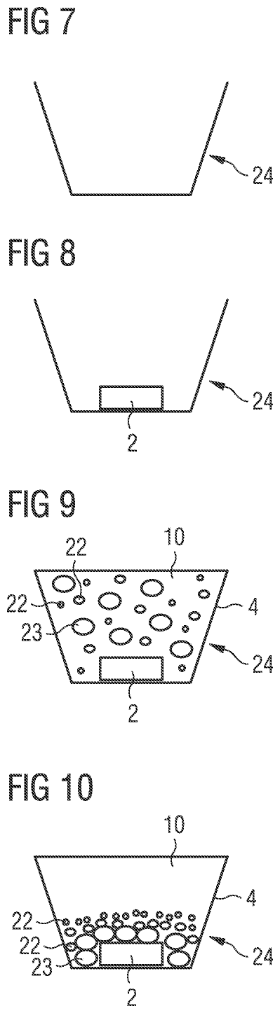

In the method according to the embodiment example of FIGS. 7 to 10, a recess 24 is provided in a first step (FIG. 7).

In a next step, the semiconductor chip 2, which emits electromagnetic radiation of a first wavelength range from a radiation exit surface during operation, is inserted into the recess 24 (FIG. 8).

As shown in FIG. 9, a matrix 10 containing phosphor particles 6 is then introduced into the recess 24. The matrix is in liquid form. The phosphor particles 6 comprise a plurality of first phosphor particles 22 and a plurality of second phosphor particles 23, wherein the first phosphor particles 22 have a higher activator concentration than the second phosphor particles 23 and the first phosphor particles 22 being more lightweighted than the second phosphor particles 23. The host lattice or at least its crystal structure and the activator are the same here.

In a next step, the phosphor particles 6 are sedimented in the matrix 10 (FIG. 10). During sedimentation, a single conversion layer 5 with first phosphor particles 22 and a single conversion layer 5 with second phosphor particles 23 are formed, whereby the single conversion layer 5 with the first phosphor particles 22 is further away from the radiation exit surface 3 of the semiconductor chip 2 than the single conversion layer 5 with the second phosphor particles 23. In this method, complete separation of the first phosphor particles 22 and the second phosphor particles 23 into two different single conversion layers 5 is generally not achieved. Then the matrix 10 is cured. The single conversion layers 5 form the conversion layer 4.

The invention is not limited to these by the description based on the embodiment examples. Rather, the invention encompasses any new feature as well as any combination of features, which in particular includes any combination of features in the patent claims, even if this feature or this combination itself is not explicitly stated in the patent claims or embodiment examples.

### LIST OF REFERENCE SIGNS

1 Optoelectronic semiconductor device
2 Semiconductor chip
3 Radiation exit surface
4 Conversion layer
5 Single conversion layer
6 Phosphor particle
8 Garnet phosphor
9 Nitride phosphor
10 Matrix
14 optical element
16 thermal connection point
17 Encapsulant
D Thickness of the conversion layer
22 first phosphor particle
23 second phosphor particle
24 Recess

1. An optoelectronic semiconductor device comprising:
a semiconductor chip configured to emit electromagnetic radiation of a first wavelength range from a radiation exit surface;
a conversion layer comprising a plurality of single conversion layers;
wherein:
each single conversion layer comprises a phosphor configured to at least partially convert electromagnetic radiation of the first wavelength range into electromagnetic radiation of a second wavelength range;
an activator concentration of the phosphor in each of the single conversion layers is different from each other;
the phosphors are introduced as phosphor particles comprising a plurality of first phosphor particles and a plurality of second phosphor particles, wherein the first phosphor particles have a higher activator concentration than the second phosphor particles; and wherein the first phosphor particles are lighter than the second phosphor particles;
the single conversion layer with the first phosphor particles is further away from the radiation exit surface of the semiconductor chip than the single conversion layer with the second phosphor particles; and
a thickness of the single conversion layers decreases starting from the radiation exit surface of the semiconductor chip.

2. The optoelectronic semiconductor device according to claim 1,
wherein the phosphor has a host lattice into which an activator is introduced, wherein the host lattice and/or the crystal structure of the host lattice and the activator of the phosphor in the single conversion layers is the same.

3. The optoelectronic semiconductor device according to claim 1,
wherein:
the conversion layer is applied to the radiation exit surface, and
the single conversion layer of the plurality of single conversion layers located closer to the radiation exit surface comprises a phosphor having an activator concentration smaller than the activator concentration of the phosphor in the single conversion layer further away from the radiation exit surface.

4. The optoelectronic semiconductor device according to claim 1,
wherein the conversion layer comprises a plurality of single conversion layers and the activator concentration of the phosphor in the single conversion layers increases starting from the radiation exit surface of the semiconductor chip.

5. The optoelectronic semiconductor device according to claim 1,
wherein:
the phosphor is formed as a plurality of phosphor particles, and
the phosphor particles are embedded in a matrix.

6. The optoelectronic semiconductor device according to claim 1,
wherein the phosphor particles comprise a garnet phosphor; a nitride phosphor; or combinations thereof.

7. The optoelectronic semiconductor device according to claim 6,
wherein the concentration of the phosphor particles in the matrix is ranges from 15 vol %, inclusive to 50 vol %, inclusive.

8. The optoelectronic semiconductor device according to claim 1,
wherein:
the phosphor is a garnet phosphor,
the activator concentration of the garnet phosphor in the single conversion layer of the plurality of single conversion layers located closest to the radiation exit surface ranges from 0.5 mol % inclusive to 2 mol % inclusive, and
the activator concentration of the garnet phosphor in the single conversion layer furthest from the radiation exit surface ranges from 1.5 mol % inclusive to 5 mol % inclusive.

9. The optoelectronic semiconductor device according to claim 1,
wherein:
the phosphor is a nitride phosphor,
the activator concentration of the nitride phosphor in the single conversion layer of the plurality of single conversion layers located closest to the radiation exit surface ranges from 0.5 mol % inclusive to 8 mol % inclusive, and
the activator concentration of the nitride phosphor in the single conversion layer furthest from the radiation exit surface ranges from 6 mol % inclusive to 20 mol % inclusive.

10. The optoelectronic semiconductor device according to claim 1,
wherein the activator concentration of the phosphor in the single conversion layer of the plurality of conversion layers furthest from the radiation exit surface differs from the activator concentration of the phosphor in the single conversion layer located closest to the radiation exit surface by at least 0.5 mol %.

11. (canceled)

12. The optoelectronic semiconductor device according to claim 1,
wherein:
the single conversion layers comprise a red-emitting phosphor, a green-emitting phosphor, a yellow-emitting phosphor, or combinations thereof; and
the semiconductor device emits white light.

13. The optoelectronic semiconductor device according to claim 1,
wherein the conversion layer fully converts the electromagnetic radiation of the first wavelength range into electromagnetic radiation of the second wavelength range.

14. A method of manufacturing an optoelectronic semiconductor device, wherein the method comprises
providing a semiconductor chip configured to emit electromagnetic radiation of a first wavelength range from a radiation exit surface;
applying a conversion layer to the radiation exit surface of the semiconductor chip; wherein the conversion layer comprises a liquid matrix and phosphor particles; wherein the conversion layer comprises a plurality of single conversion layers formed on the radiation exit surface;
wherein:
each single conversion layer of the plurality of single conversion layers comprises a phosphor configured to at least partially convert electromagnetic radiation of the first wavelength range into electromagnetic radiation of a second wavelength range, and
an activator concentration of the phosphor in the single conversion layers is different from each other; and
a thickness of the plurality of single conversion layers decreases starting from the radiation exit surface of the semiconductor chip.

15. The method according to claim 14, wherein the single conversion layers are applied one after the other using a spray coating.

16. The method according to claim 14, wherein:
the phosphor is present as phosphor particles embedded in a matrix, and
the phosphor particles are sedimented in the matrix.

17. The method according to claim 16,
wherein:
the phosphor particles comprise a plurality of first phosphor particles and a plurality of second phosphor particles, wherein the first phosphor particles comprise a higher activator concentration than the second phosphor particles, and wherein the first phosphor particles are lighter than the second phosphor particles,
the phosphor particles are introduced into the matrix and sedimented to form a single conversion layer with first phosphor particles and a single conversion layer with second phosphor particles, wherein the single conversion layer with the first phosphor particles is further away from the radiation exit surface of the semiconductor chip than the single conversion layer with the second phosphor particles.
